(19) United States
(12) Patent Application Publication
(10) Pub. No.: US 2024/0355787 A1
(43) Pub. Date: Oct. 24, 2024

(54) Color-On-Encapsulation Patterning for Inconspicuous Display Transmittance Enhancement

(71) Applicant: Google LLC, Mountain View, CA (US)

(72) Inventors: Guillaume Lestoquoy, Mountain View, CA (US); Ion Bita, Los Altos, CA (US)

(73) Assignee: Google LLC, Mountain View, CA (US)

(21) Appl. No.: 18/672,950

(22) Filed: May 23, 2024

Related U.S. Application Data
(60) Provisional application No. 63/649,603, filed on Jan. 1, 0001.

(51) Int. Cl. H01L 25/075; H01L 25/16; H01L 33/58

(52) U.S. Cl. CPC H01L 25/0753; H01L 25/167; H01L 33/58

(57) ABSTRACT

This document describes systems and techniques directed at incorporating a non-uniform aperture region in a transmittance-limiting layer, such as a color-on-encapsulation (COE) layer, to increase a transmittance of electromagnetic energy receivable by and/or radiated from an under-display sensor positioned under a display panel. The non-uniform aperture layer maintains or increases the transmittance of the electromagnetic energy while being less visually conspicuous than a uniform aperture region. In aspects, a display panel stack includes a cover layer, a pixel array, and a transmittance-limiting layer disposed between the cover layer and the pixel array configured to at least partially absorb electromagnetic energy incident at a surface of the transmittance-limiting layer. The transmittance-limiting layer includes a non-uniform aperture region having a plurality of apertures configured to at least partially permit the transmission of the electromagnetic energy that is detectable by an under-display sensor.

### CROSS-REFERENCE TO RELATED APPLICATION(S)

This application claims the benefit of U.S. Provisional Patent Application Ser. No. 63/649,603, filed on May 20, 2024, the disclosure of which is incorporated by reference herein in its entirety.

### SUMMARY

This document describes systems and techniques directed to incorporating a non-uniform aperture region in a transmittance-limiting layer, such as a color-on-encapsulation (COE) layer, to increase the transmittance of electromagnetic energy receivable by and/or radiated from an under-display sensor positioned under a display panel stack. The non-uniform aperture layer increases the transmittance of the electromagnetic energy while being less-visually conspicuous than a uniform aperture region.

In aspects, a display panel stack includes a cover layer, a pixel array, and a transmittance-limiting layer disposed between the cover layer and the pixel array configured to at least partially absorb electromagnetic energy incident at a surface of the transmittance-limiting layer. The transmittance-limiting layer includes a non-uniform aperture region having a plurality of apertures configured to at least partially permit the transmission of the electromagnetic energy that is detectable by an under-display sensor.

This Summary is provided to introduce simplified concepts of systems and techniques of color-on-encapsulation patterning for inconspicuous display transmittance enhancement, the concepts of which are further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques directed at color-on-encapsulation patterning for inconspicuous display transmittance enhancement are described in this document with reference to the following drawings:

FIG. 1 illustrates a partial cross-sectional view of an example display panel stack incorporating a non-uniform aperture region in a transmittance-limiting layer;

FIG. 2 illustrates another partial cross-sectional view of the example display module of FIG. 1 showing a sensing field of view of an under-display sensor;

FIGS. 3, 4, 5, and 6 illustrate partial, cross-sectional views of transmittance-limiting layers incorporating alternative implementations of non-uniform aperture regions;

FIG. 7 illustrates a schematic view of a non-uniform aperture region in which sizes of the plurality of apertures are varied over the non-uniform aperture region;

FIG. 8 illustrates a perspective view of a display panel stack including the non-uniform aperture region of FIG. 7;

FIG. 9 illustrates a schematic view of a non-uniform aperture region in which distances are varied between apertures of the plurality of apertures;

FIG. 10 illustrates a perspective view of a display panel stack including the non-uniform aperture region of FIG. 9;

FIG. 11 illustrates a schematic view of a plurality of apertures of decreasing aperture positioned at an increasing distance between two or more apertures of the plurality of apertures in a non-uniform aperture region;

FIG. 12 illustrates a block diagram of an example electronic device in which a display panel stack including a non-uniform aperture region may be used; and

FIG. 13 illustrates a flow diagram of an example method of forming a non-uniform aperture region in a transmittance-limiting layer of a display panel stack.

The same numbers are used throughout the Drawings to reference like features and components.

### DETAILED DESCRIPTION

### Overview

Many electronic devices include displays, such as light-emitting diode (LED) displays and liquid crystal displays (LCDs). Display panel stacks of these electronic devices often include a pixel array having tens of thousands of pixels organized into a two-dimensional grid (e.g., a circular grid, a rectangular grid). Many of these electronic devices also include cameras, light sensors, or other electromagnetic sensors to record images, use facial recognition to authenticate users, adjust display brightness based on ambient light levels, or perform other functions. In some electronic devices, one or more of the electromagnetic sensors are positioned in an inset window at an edge of the display or in a cut-out region of the display. In other electronic devices, to avoid including an inset window or a cut-out region, the one or more electromagnetic sensors are positioned beneath the pixel array.

Display panel stacks also commonly include a transmittance-limiting layer to minimize reflections that may otherwise appear from the pixel array. The transmittance-limiting layer may be formed of a polarizing layer or a color-on-encapsulation (COE) layer. The transmittance-limiting layer limits the amount of electromagnetic energy incident at a surface of the display panel stack, thereby minimizing reflections at the pixel array. In so doing, however, the transmittance-limiting layer also limits the amount of the electromagnetic energy detectable at an under-display sensor positioned beneath a transmittance-limiting layer. As a result, the under-display sensor may not receive sufficiently-high amounts of electromagnetic energy to detect information and/or perform intended functions.

To enable more electromagnetic energy to pass through the transmittance-limiting layer and reach the under-display sensor, a group of small openings may be formed in the transmittance-limiting layer over a position of the under-display sensor. Such a solution, however, may be visually discernible by users and may detract from user experience.

To increase an amount of electromagnetic energy received by under-display sensors and, simultaneously, reduce an inconspicuousness of the openings, perforations or other substantially-transparent sections in the transmittance-limiting layer may be arranged in a non-uniform pattern, defining a non-uniform aperture region of the transmittance-limiting layer. The non-uniform aperture region may maintain or increase the transmittance of electromagnetic energy while being less visually-conspicuous than a uniform aperture region.

### Example Implementations

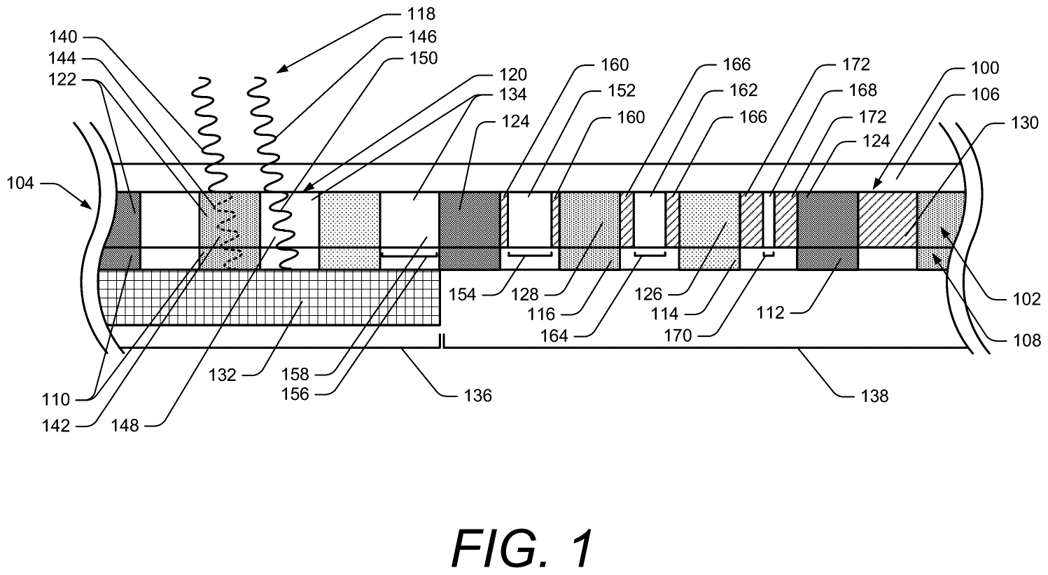

FIG. 1 illustrates an example non-uniform aperture region 100 formed in an example transmittance-limiting layer 102 of an example display panel stack 104. In the display panel stack 104, the transmittance-limiting layer 102 is disposed between a cover layer 106 and a pixel array 108 that includes multiple pixels 110. In implementations, the cover layer 106 may include a glass or plastic panel. The plurality of pixels 110 in the pixel array 108 may include one or more red pixels 112, green pixels 114, and blue pixels 116.

The transmittance-limiting layer 102 may include a color-on-encapsulation (COE) layer, as in the present example. In additional implementations, the transmittance-limiting layer 102 may include a polarized layer or another layer configured to at least partially absorb electromagnetic energy 118 incident at a surface 120 of the transmittance-limiting layer 102. As a result of at least partially absorbing the electromagnetic energy 118, the transmittance-limiting layer 102 minimizes a reflection (not shown) of the electromagnetic energy 118, thereby causing the display panel stack 104 to appear to be generally black in color, rather than a reflective, mirrored surface that may otherwise be presented by the pixel array 108 without inclusion of the transmission-limiting layer 102.

In the example of FIG. 1 and the following description, the transmittance-limiting layer 102 includes a COE layer and, thus, includes a plurality of colored filters 122. The plurality of colored filters 122 may include one or more red filters 124, green filters 126, and blue filters 128 that facilitate the transmission of the associated color of light. Each of the filters 124, 126, and 128 is aligned with correspondingly-colored pixels 112, 114, and 116. As a result, the filters 124, 126, and 128 substantially transmit light generated by the correspondingly-colored pixels 112, 114, and 116 while the filters 124, 126, and 128 absorb other colors of light included in the incident electromagnetic energy 118 to suppress reflections, as previously described. In general, around and between the plurality of colored filters 122, the transmittance-limiting layer 102 includes an opaque or substantially opaque substrate 130 that generally absorbs the incident electromagnetic energy 118.

The transmittance-limiting layer 102 may interfere with operation of an under-display sensor 132 that may be positioned beneath the display panel stack 104. The under-display sensor 132 may include a camera, a light-level sensor, or an infrared sensor that is used to capture images, provide input to a display generator, or recognize proximity to a body or other heat source, respectively, which may be used to authenticate a user, adjust screen brightness, reject input from unintended touches, or other functions. The under-display sensor 132 may utilize one or more wavelengths of electromagnetic energy detectable by the under-display sensor 132. It may be desirable to include a sensor under the display panel stack 104 rather than create insets or cut-out regions in the display panel stack 104 which would interfere with a seamless appearance of the display panel stack 104. However, because the transmittance-limiting layer 102 may limit an amount of the electromagnetic energy 118 from passing through the transmittance-limiting layer 102 to prevent undesirable reflections, the transmittance-limiting layer 102 also may prevent the electromagnetic energy 118 from reaching the under-display sensor 132 and, thus, potentially interfere with the operation of the under-display sensor 132.

Including openings in the transmittance-limiting layer 102 over the under-display sensor 132 (e.g., removing portions of the substrate 130 of the transmittance-limiting layer 102) may allow the electromagnetic energy 118 to pass through the transmittance-limiting layer 102 to facilitate operation of the under-display sensor 132. Unfortunately, openings in the transmittance-limiting layer 102 can substantially disrupt the seamless appearance of the display panel stack 104 similar to the way that including insets or cut-outs (not shown) in the display panel stack 104 would. To this end, the transmittance-limiting layer 102 may include non-uniform (e.g., non-uniformly shaped, non-uniformly spaced) apertures (e.g., perforations) in the transmittance-limiting layer 102, defining the non-uniform aperture region 100 and reducing a visual-discernibility of the non-uniform aperture region 100 in the transmittance-limiting layer 102.

In aspects, between the plurality of colored filters 122 in the non-uniform aperture region 100, a plurality of apertures 134 are formed within a first portion 136 of the non-uniform aperture region 100. In some implementations, the first portion 136 corresponds to a position of the under-display sensor 132. In a second portion 138 of the non-uniform aperture region 100, a size of the apertures 134 may decrease and/or a distance between two or more apertures of the plurality of apertures 134 may increase, causing an appearance of the plurality of apertures 134 to appear more diffuse or to appear to fade, lessening a visual contrast of the non-uniform aperture region 100 with the rest of the display panel stack 104. In the example of FIG. 1, the plurality of apertures 134 in the second portion 138 of the non-uniform aperture region 100 are uniformly spaced, but a size of the apertures 134 are successively reduced in size. Examples of increasing the distance between the apertures 134 and/or increasing the distance while also reducing the size of the apertures 134 are described below.

The apertures 134 may include perforations or other physical holes formed in the transmittance-limiting layer 102. Alternatively, or additionally, the apertures 134 may include substantially-transparent sections of material disposed between the filters 122 of the transmittance-limiting layer 102 that allow one or more wavelengths of the electromagnetic energy 118 to pass through the transmittance-limiting layer 102. In either case, a first electromagnetic energy wave 140 that is incident upon a first filter 142 is generally blocked or attenuated by the first filter 142, resulting in a highly diminished first electromagnetic energy wave 144 passing through the first filter 142. By contrast, a second electromagnetic energy wave 146 that is incident upon a first aperture 148 at least partially permits transmission of the second electromagnetic energy wave 146, resulting in a substantially-undiminished second energy wave 150 passing through the transmittance-limiting layer 102 to the under-display sensor 132.

The apertures 134 in the first portion 136 of the non-uniform aperture region 100 may be sized (or spaced) to at least partially permit transmission of the electromagnetic energy 118 that is incident on the surface 120 of the transmittance-limiting layer 102. By contrast, the apertures 134 included in the second portion 138 of the non-uniform aperture region 100 have successively smaller aperture sizes to reduce the discernible visual appearance of the apertures 134 in the second portion 138 of the non-uniform aperture region 100. In some implementations, the second portion 138 of the non-uniform aperture region 100 may not be positioned over the under-display sensor 132, so there may be less of a need for the apertures 134 in the second portion 138 to permit a transmission of the electromagnetic energy 118. The configuration of the apertures within the second portion 138 of the non-uniform aperture region 100 may be for the purpose of diffusing the appearance of the non-uniform aperture region 100 to render the non-uniform aperture region less visually-conspicuous.

A first reduced aperture 152 of the second portion 138 of the non-uniform aperture region 100 has a first reduced size 154 that is less than a size 156, for example, of a full-sized aperture 158 in the first portion 136 that is positioned at a location that is over the under-display sensor 132. First sections 160 of the substantially opaque substrate 130 are left in place around the first reduced aperture 152. Moving away from the under-display sensor 132, a second reduced aperture 162 of the second portion 138 of the non-uniform aperture region 100 has a second reduced size 164 that is less than the first reduced size 154 of the first reduced aperture 152 with second sections 166 of the substantially opaque substrate 130 left in place around the second reduced aperture 162. A third reduced aperture 168 of the second portion 138 of the non-uniform aperture region 100 has a third reduced size 170 that is less than the second reduced size 164 of the second reduced aperture 162 with third sections 172 of the substantially opaque substrate 130 left in place around the third reduced aperture 168.

The sizes 154, 164, and 170 may decrease uniformly or pseudo-randomly between the first portion 136 of the non-uniform aperture region 100 and the second portion 138 of the non-uniform aperture region 100. For example, the sizes 154, 164, and 170 may decrease by a uniform lateral dimension or uniform reduction in area. Alternatively, a difference in sizes 154 and 164 may be reduced by one proportion and the difference between sizes 164 and 170 may be reduced by a different proportion. For another example, the sizes 154 and 164 of the first reduced aperture 152 and the second reduced aperture 162, respectively, may be the same, while the size 170 of the third reduced aperture 168 may then be reduced relative to the sizes 154 and 164. The conspicuousness of the apertures 134 in the non-uniform aperture region 100 may be diminished by changing sizes of the apertures 134 or by changing the distances between the apertures 134 without reducing the sizes of the apertures 134 according to any particular pattern, formula, or rule.

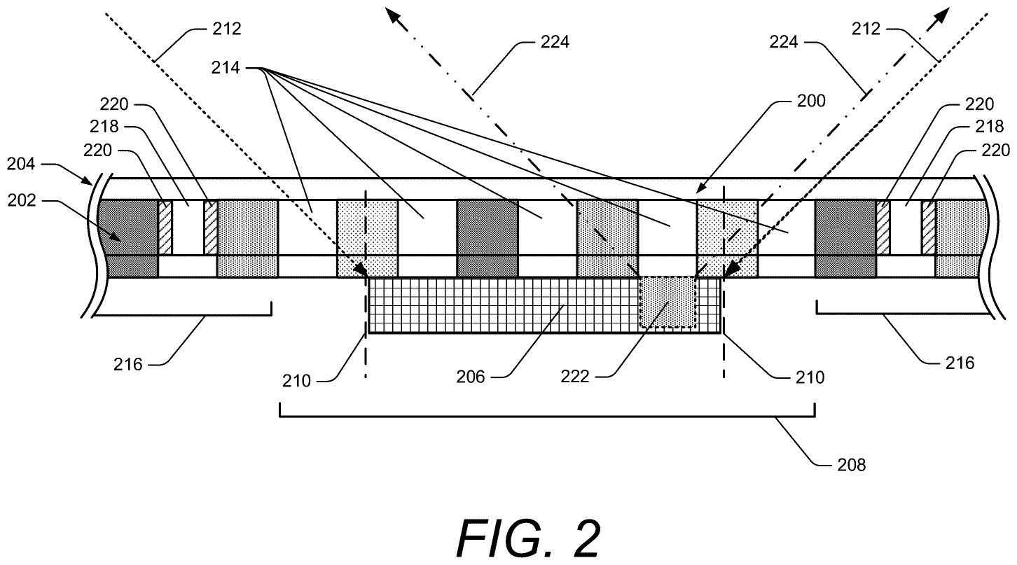

FIG. 2 illustrates another example implementation of an example non-uniform aperture region 200 of an example transmittance-limiting layer 202 of an example display panel stack 204 positioned over an under-display sensor 206. As illustrated in FIG. 2, the non-uniform aperture region 200 may extend beyond a length and/or width of the under-display sensor 206 and, thus, the non-uniform aperture region 200 may extend around the under-display sensor 206 in a plane of the display stack 204 as described below. In addition, it should be appreciated that a first portion 208 of the non-uniform aperture region 200 may extend beyond edges 210 of the under-display sensor 206.

In aspects, to accommodate a sensing field of view 212 (represented as in-bound arrows in dotted lines in FIG. 2) of the under-display sensor 206, an array of full-sized apertures 214 may be desirable so as to fully facilitate an ability of the under-display sensor 206 to receive electromagnetic energy (not shown in FIG. 2). The sensing field of view 212 may extend beyond the edges 210 of the under-display sensor 206. Accordingly, the first portion 208 of the non-uniform aperture region 200 including the array of full-sized apertures 214 may extend beyond the edges 210 of the under-display sensor 206. Accordingly, a second portion 216 of the non-uniform aperture region 200 including reduced-size apertures 218 (in which sections 220 of the substantially opaque substrate 130 of FIG. 1 left in place around the reduced-size apertures 218) are disposed outside the sensing field of view 212 of the under-display sensor 206.

In aspects, the under-display sensor 206 may include or be associated with an electromagnetic emitter 222 that generates electromagnetic energy across a transmission range 224 (represented as out-bound arrows in dotted-and-dashed lines in FIG. 2) which, when reflected by an external object (not shown) is received by the under-display sensor 206. The electromagnetic emitter 222 may generate, for example, visible light, infrared light, or other electromagnetic energy that may provide reflected input to the under-display sensor 206. In such a case, the first portion 208 and the second portion 216 of the non-uniform aperture region 200 may be configured to facilitate the ability of the electromagnetic emitter 222 to transmit electromagnetic energy through the transmittance-limiting layer 202. The transmission range 224 may be less than, the same as, or greater in size than the sensing field of view 212. In any case, the first portion 208 of the non-uniform aperture region 200 may extend beyond the edges 210 of the under-display sensor 206 to accommodate the transmission range 224 whether or not it is necessary to extend the first portion 208 of the non-uniform aperture region 200 for the sake of accommodating the sensing field of view 212 of the under-display sensor 206. In other words, the transmittance-limiting layer 202 is configured to at least partially permit the transmission of electromagnetic energy that is detectable by the under-display sensor 206 and/or to at least partially permit the transmission of generated electromagnetic energy produced by an electromagnetic emitter 222 associated with the under-display sensor 206.

### Example Configurations of Non-Uniform Aperture Regions

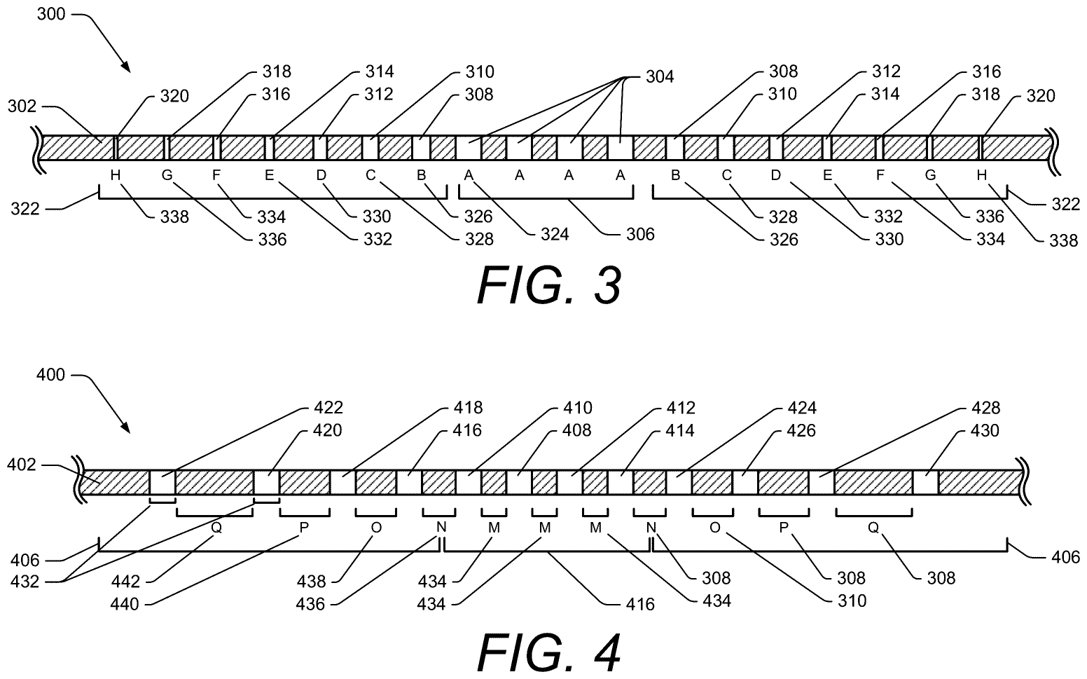

FIGS. 3-11 illustrate different configurations of non-uniform aperture regions that may be used in a display panel stack to facilitate operation of the under-display sensors 132 and 206 as described with reference to FIGS. 1 and 2 while seeking to render apertures in the transmittance-limiting layers 102 and 202, respectively, less visually-conspicuous. In aspects, a size of the apertures and/or a distance between two or more of the apertures are varied to make the non-uniform aperture regions less visually-conspicuous.

FIGS. 3-7 illustrate cross-sectional views of non-uniform aperture regions to render the apertures in respective transmittance-limiting layers less visually-conspicuous. FIG. 3 illustrates a cross-sectional view of a non-uniform aperture region 300 of a transmittance-limiting layer 302 including a plurality of full-sized apertures 304 in a first portion 306 of the non-uniform aperture region 300 and a plurality of apertures 308, 310, 312, 314, 316, 318, and 320 of uniformly-decreasing size in a second portion 322 of the transmittance-limiting layer 300 disposed around the plurality of full-sized apertures 304 in the first portion 306. It will be appreciated that the cross-sectional view of FIG. 3 illustrates two second regions 322 because the second region 322 surrounds (e.g., encircles) the first region 306. In the example of FIG. 3, the non-uniform aperture region 300 is symmetrical with the plurality of apertures 308, 310, 312, 314, 316, 318, and 320 in the second portion 322 extending away from the first portion 306 in every direction in a plane of the non-uniform aperture region 300.

The full-sized apertures 304 in the first portion 306 of the non-uniform aperture region 300 are of a same size A 324 where A 324 represents a diameter or other measure of size on an order of a fraction of a millimeter. The plurality of apertures 308, 310, 312, 314, 316, 318, and 320 of uniformly decreasing size in the second portion 322 have diameters or other measures of size of B 326, C 328, D 330, E 332, F 334, G 336, and H 338 decrease uniformly from size B 326 to size H 338. The uniform decrease may be evenly proportioned, for example, where each of the sizes is half or another fraction of a size of the next largest of the plurality of apertures 308, 310, 312, 314, 316, 318, and 320 where C 328 is half the size of B 326, etc. Alternatively, each of the sizes may be a fixed amount smaller than a next largest of the plurality of apertures 308, 310, 312, 314, 316, 318, and 320, for example, each of the plurality of apertures 308, 310, 312, 314, 316, 318, and 320 may be reduced by one-seventh of B 326 so that C 328 is six-sevenths of B 326 and H 338 is one-seventh of B 326. In implementations, outside of the second portions 322 (e.g., beyond the apertures H 320), there are no further apertures such that the transmittance-limiting layer 302 then assumes a continuous form that is not interrupted by apertures.

In non-uniform aperture region 300 of FIG. 3, centers of the apertures 304, 308, 310, 312, 314, 316, 318, and 320 may have centers that are evenly-spaced apart and the visual diminishing of the apertures 304, 308, 310, 312, 314, 316, 318, and 320 is achieved by reducing the size of the apertures, 324, 326, 328, 330, 332, 334, 336, and 338. By contrast, instead of changing sizes of the apertures, apertures in a second portion may be spaced successively further apart to achieve an appearance of diffusing a non-uniform aperture region to render the non-uniform aperture region less visually conspicuous, as described with reference to FIG. 4.

FIG. 4 illustrates a cross-sectional view of a non-uniform aperture region 400 of a transmittance-limiting layer 402 in which both a first region 404 and a second region 406 of the non-uniform aperture region 400 includes a plurality of apertures 408, 410, 412, and 414 in a first portion 404 of the non-uniform aperture region 400 and a plurality of apertures 416, 418, 420, 422, 424, 426, 428, and 430 are all of a same size 432. As in the non-uniform aperture region 300 of FIG. 3 the apertures 408, 410, 412, and 414 in the first region 404 of the non-uniform aperture region 400 are of the same size 432 and are also evenly spaced at a distance between two adjacent apertures of M 434. By contrast, different from the non-uniform aperture region 300 in which the apertures 308, 310, 312, 314, 316, 318, and 320 in the second portion 322 were evenly spaced, the apertures 416, 418, 420, 422, 424, 426, 428, and 430 in the second portion 406 of the non-uniform aperture region 400 are spaced apart at different distances N 436, O 438, P 440, and Q 442.

For example, the apertures 416 and 424 in the second region 406 closest to the first region 404 are spaced apart from the apertures 410 and 414, respectively, by the distance N 436. The apertures 418 and 426 in the second region 406 are spaced from the next closest apertures 410 and 414, respectively, in the second region by the distance O 438, which is greater than the distance N 436. Similarly, continuing to move away from the first region 404, the remaining apertures 420, 422, 428, and 430 are spaced apart from the next closest apertures by increasing distances P 440 and Q 442. The increasing distances from the first portion N 436, O 438, P 440, and Q 442 cause the appearance of the non-uniform aperture region 400 to appear more diffuse or to fade away from the first portion 404 and, thus, the non-uniform aperture region 400 is less visually conspicuous than if the apertures were of equal size and spaced apart at a same distance.

Implementations of a non-uniform aperture region are not restricted to uniformly reducing a size of the apertures moving away from a first portion or uniformly increasing a distance between two or more apertures moving away from the first portion. Not only can reducing a size of the apertures be combined with increasing a distance between two or more apertures moving away from the first portion, as further described below, but neither the change in size of the apertures nor the changing distance between apertures need be uniform.

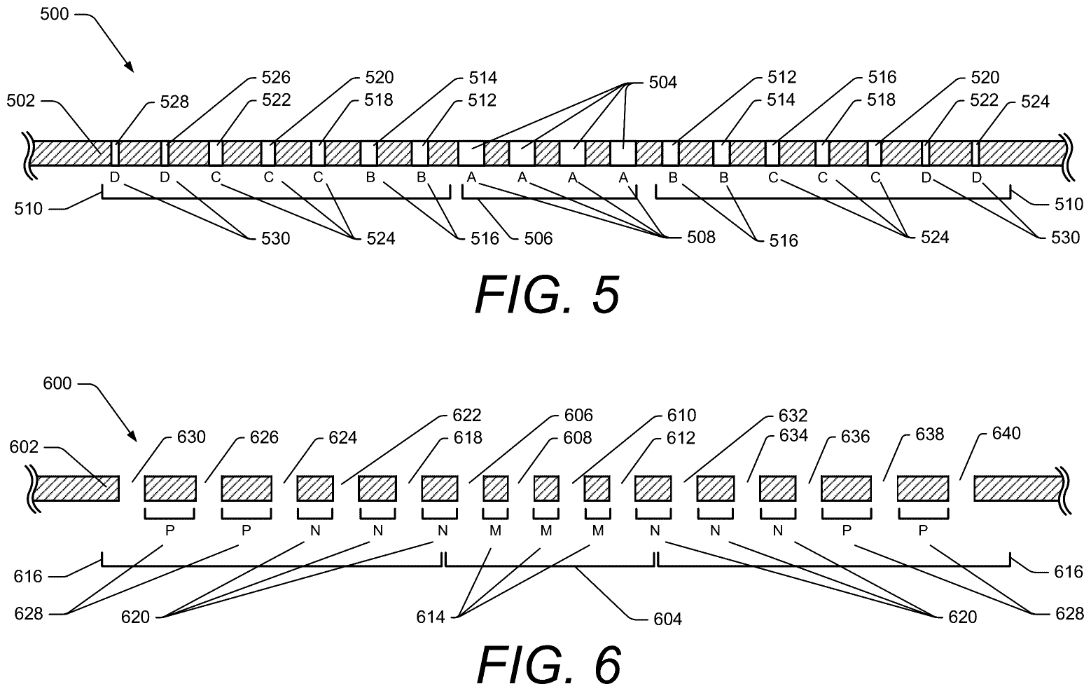

FIG. 5 illustrates a cross-sectional view of a non-uniform aperture region 500 of a transmittance-limiting layer 502 in which aperture size changes in a pseudo-random pattern rather than changing uniformly. A plurality of full-sized apertures 504 are arrayed in a first portion 506 of the non-uniform aperture region 500. Each of the apertures 504 in the first portion 506 is of a size A 508. In a second portion 510, two pairs of apertures 512 and 514 adjacent to the first portion 506 are of a size B 516 that is smaller than a 508. Moving away from the first portion 506, adjacent to the pair of apertures 514, three pairs of apertures 518, 520, and 522 all are of a size C 524 that is smaller than B 516, a size of the next closest pair of apertures 514. Moving still further away from the first portion 506, adjacent to the pair of apertures 522 are two pairs of apertures 526 and 528 of a size D 530 that is smaller than size C 524, a size of the next closest pair of apertures 522. The successive but non-uniform pseudo-random pattern of reducing size of the apertures 512, 514, 518, 520, 522, 526, and 528 in the second portion 510 achieves an appearance of diffusing the non-uniform aperture region 500 to render the non-uniform aperture region 500 less visually-conspicuous.

FIG. 6 illustrates a cross-sectional view of a non-uniform aperture region 600 of a transmittance-limiting layer 602 in which aperture size remains constant, but a distance between the apertures changes in a non-uniform, pseudo-random pattern rather than changing uniformly. A first portion 604 of the non-uniform transmittance region 600 includes apertures 606, 608, 610, and 612 that are separated by a distance M 614. Moving one direction away from the first portion 604 into a second region 616 of the non-uniform aperture region 600, an aperture 618 is separated from the aperture 606 by a distance N 620. Continuing to move away from the first portion 604 of the non-uniform aperture region 600, an aperture 622 is separated from the aperture 618 by the distance N 620, and an aperture 624 is separated from the aperture 622 by the distance N 620. Moving further away from the first portion 604 of the non-uniform aperture region 600, an aperture 626 is separated from the aperture 624 by a distance P 628, where the distance P 628 is greater than the distance N 620. Similarly, an aperture 630 is also separated from the aperture 626 by the same distance P 628. Moving away from the first portion 604 in another direction into the second region 616, aperture 632 is separated by the aperture 612 by the distance N 620, aperture 634 is separated from the aperture 632 by the distance N 620, and aperture 636 is separated from the aperture 634 by the distance N 620. Aperture 638 is separated from the aperture 636 by the distance P 628 and the aperture 640 is separated from the aperture 638 by the distance P 628.

Two things should be noted with regard to the cross-sectional view of FIG. 6. First, the apertures 606, 608, 610, 612, 618, 622, 625, 630, 632, 634, 636, 638, and 640 are shown as openings in the transmittance-limiting layer 602. The apertures may be physical perforations or other openings in the transmittance-limiting layer 602. These open apertures may be formed by laser drilling the apertures in the transmittance-limiting layer 602 or may be formed as part of a deposition process of forming the transmittance-limiting layer 602. In implementations, instead of comprising openings, the apertures may be comprised of substantially-transparent sections of the transmittance-limiting layer 602 formed as part of molding, depositing, or otherwise forming the transmittance-limiting layer 602. The substantially-transparent sections may be configured to permit transmission of at least one or more wavelengths of electromagnetic energy detectable by the under-display sensor. Second, although apertures 606, 608, 610, 612, 618, 622, 625, 630, 632, 634, 636, 638, and 640 are of equivalent size and the apertures are just spaced apart by different distances, both the size of the apertures and the distances between the apertures may be varied, cither uniformly or pseudo-randomly, as further described below.

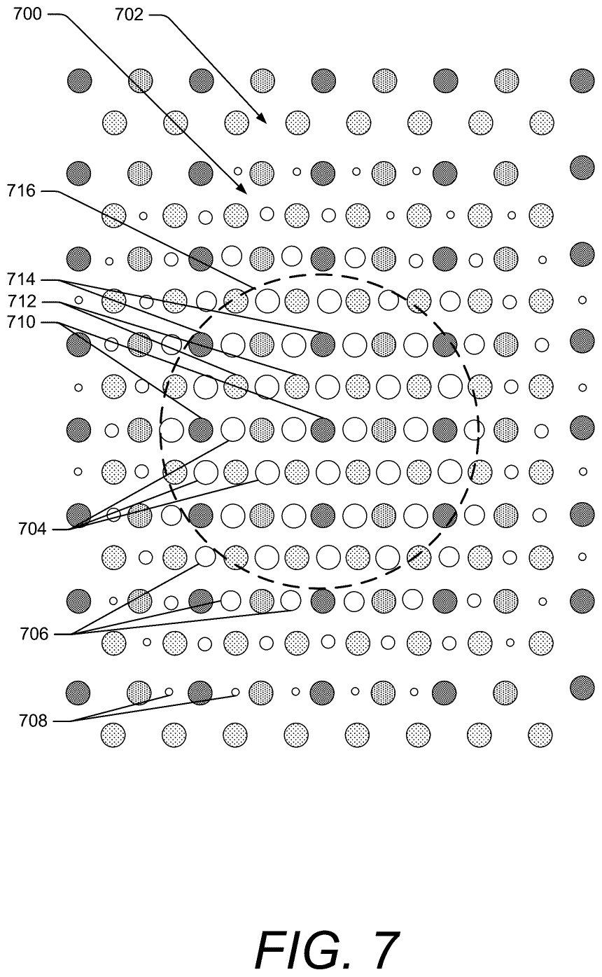

FIG. 7 illustrates an enlarged, top-down view of a non-uniform aperture region 700 of a transmittance-limiting layer 702. The non-uniform aperture region 700 comprises a plurality of apertures 704, 706, and 708 of varying size formed in the transmittance-limiting layer 702, interspersed in interstices between pixels 710, 712, and 714. The under-display sensor 716 (represented by a dashed line in FIG. 7) is positioned beneath the pixels 710, 712, and 714, which may include red pixels 710, green pixels 712, and blue pixels 714. As previously described, the apertures 704, 706, and 708 may include perforations or other physical openings in the transmittance-limiting layer 702 or substantially-transparent sections formed in the transmittance-limiting layer 702. To facilitate the ability of the under-display sensor 716 to receive (or radiate) electromagnetic energy and, thus, facilitate operation of the under-display sensor 716, largest apertures 704 are arrayed between the pixels 710, 712, and 714 over the under-display sensor 716 (or within a sensing field of view of the under-display sensor 716, as previously described). Medium-sized apertures 706, smaller in size than the largest apertures 704, are disposed just outside a perimeter of the under-display sensor 716. Small apertures 708, smaller in size than the medium-sized apertures 706, are disposed just outside the medium-sized apertures 706. Small apertures 708, smaller in size than the medium-sized apertures 706, are disposed beyond the medium-sized apertures 706. At a distance from the under-display sensor 716, no additional apertures are included. Thus, the apertures 704, 706, and 708 diminish or fade from the large apertures 704 over the under-display sensor 716 to a portion of the transmittance-limiting layer 702 including no apertures.

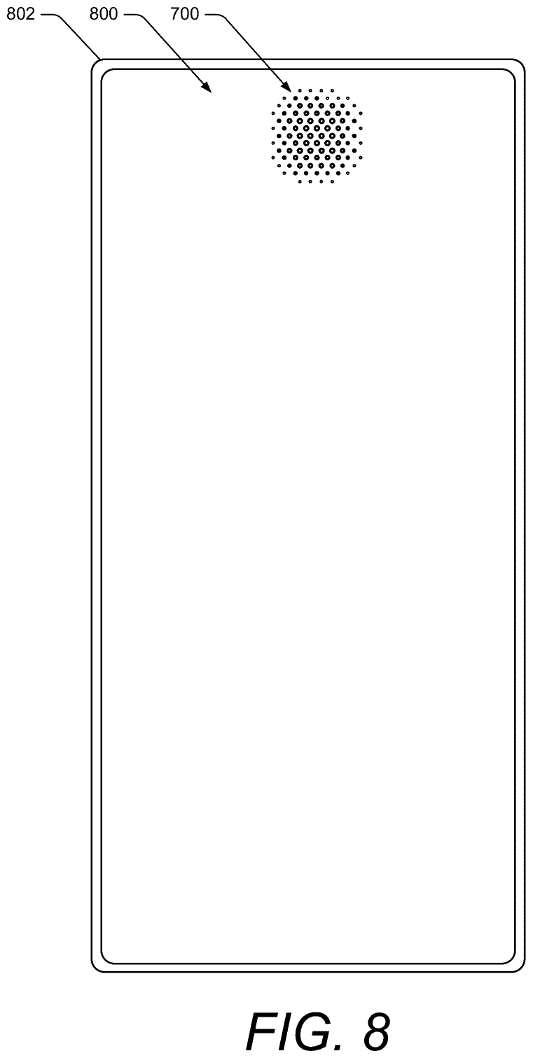

FIG. 8 shows a display 800 of an electronic device 802, such as a mobile telephone, including the non-uniform aperture region 700 of FIG. 7 in which the non-uniform aperture region is comprised of apertures of equal size disposed over an under-display sensor (not shown in FIG. 8). The non-uniform aperture region 700, by seeming to diminish or fade from a position of the under-display sensor (not shown in FIG. 8) through the use of apertures of diminishing size, the appearance of the non-uniform aperture region 700 appears to be less visually-conspicuous as compared to a region of equally-sized, equally-spaced apertures.

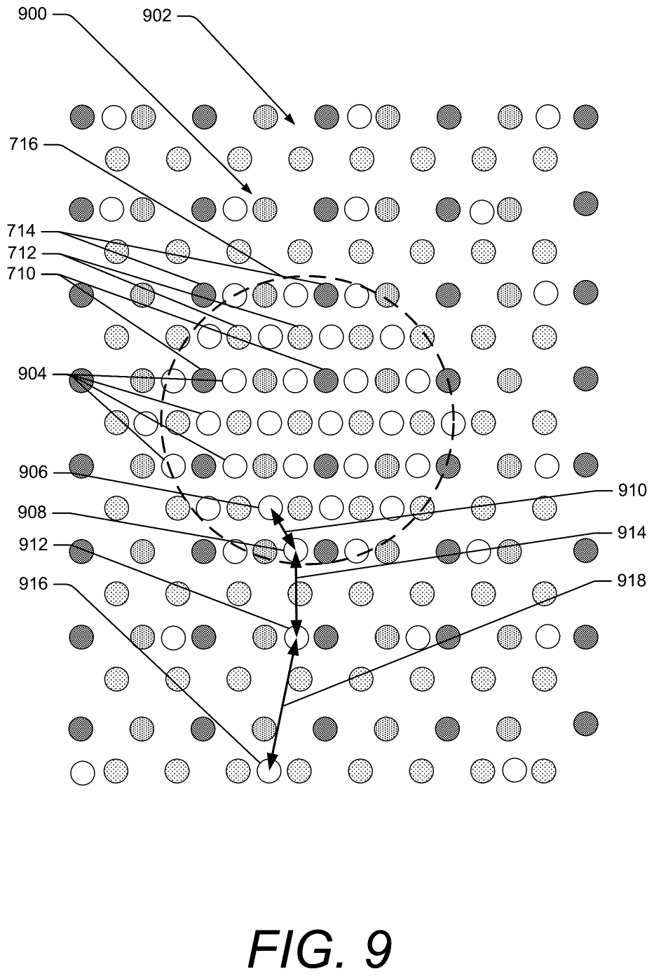

FIG. 9 illustrates an enlarged, top-down view of a non-uniform aperture region 900 of a transmittance-limiting layer 902. The non-uniform aperture region 900 comprises a plurality of apertures 904 of equal size formed in the transmittance-limiting layer 902 at varying distances between the pixels 710, 712, and 714. Again, the under-display sensor 716 (represented by a dashed line in FIG. 9) is positioned beneath the pixels 710, 712, and 714. As previously described, the apertures 904 may include perforations or other physical openings in the transmittance-limiting layer 902 or substantially-transparent sections formed in the transmittance-limiting layer 902. To facilitate the ability of the under-display sensor 716 to receive (or radiate) electromagnetic energy and, thus, facilitate operation of the under-display sensor 716, the apertures 904 are densely positioned between the pixels 710, 712, and 714 over the under-display sensor 716 (or within a sensing field of view of the under-display sensor 714, as previously described). In implementations, the apertures 904 may be disposed at every available location between the pixels 710, 712, and 714 over the under-display sensor 716.

Instead of decreasing the size of the apertures 904 away from the under-display sensor 716, as in the example of FIG. 7, the apertures 904 are positioned at increasing distances from each other further away from the under-display sensor 716. For example, a first aperture 906 and a second aperture 908 over the under-display sensor 716 are separated by a first distance 910. Moving away from the under-display sensor 716, a third aperture 912 is separated by a second distance 914 from the second aperture 908, where the second distance 914 is greater than the first distance 910. Moving still away from the under-display sensor 716, a fourth aperture 916 is separated by a third distance 918 from the third aperture 912, where the third distance 918 is greater than the second distance 914.

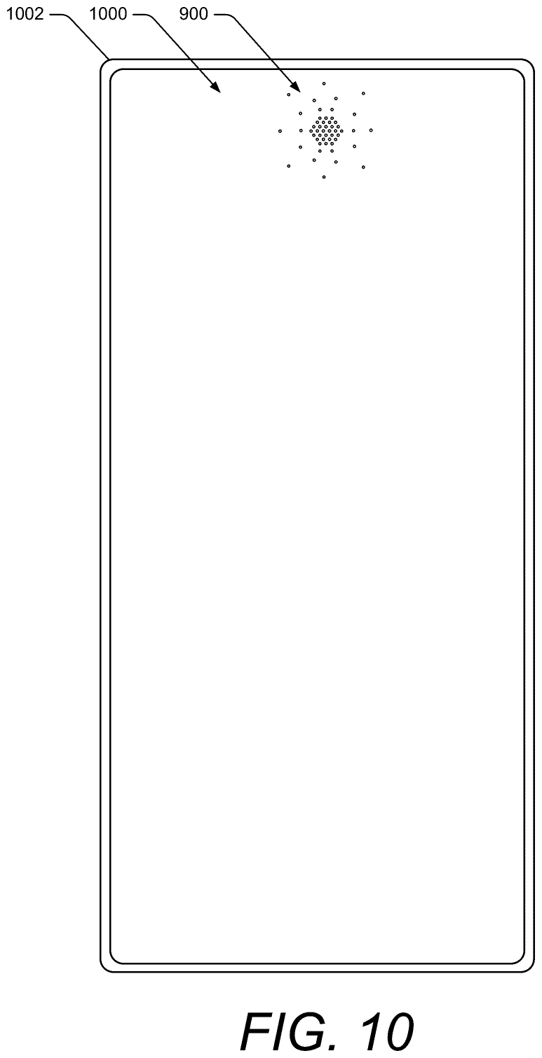

FIG. 10 shows a display 1000 of an electronic device 1002, such as a mobile telephone, including the non-uniform aperture region 900 of FIG. 9 in which the non-uniform aperture region is comprised of apertures of equal size that are separated by increasing distances as the apertures are further away an under-display sensor (not shown in FIG. 10). The non-uniform aperture region 900, by seeming to diminish or fade from a position of the under-display sensor through the use of apertures that are separated by increasing distances, the appearance of the non-uniform aperture region 900 appears to be less visually-conspicuous as compared to a region of equally-sized, equally-spaced apertures.

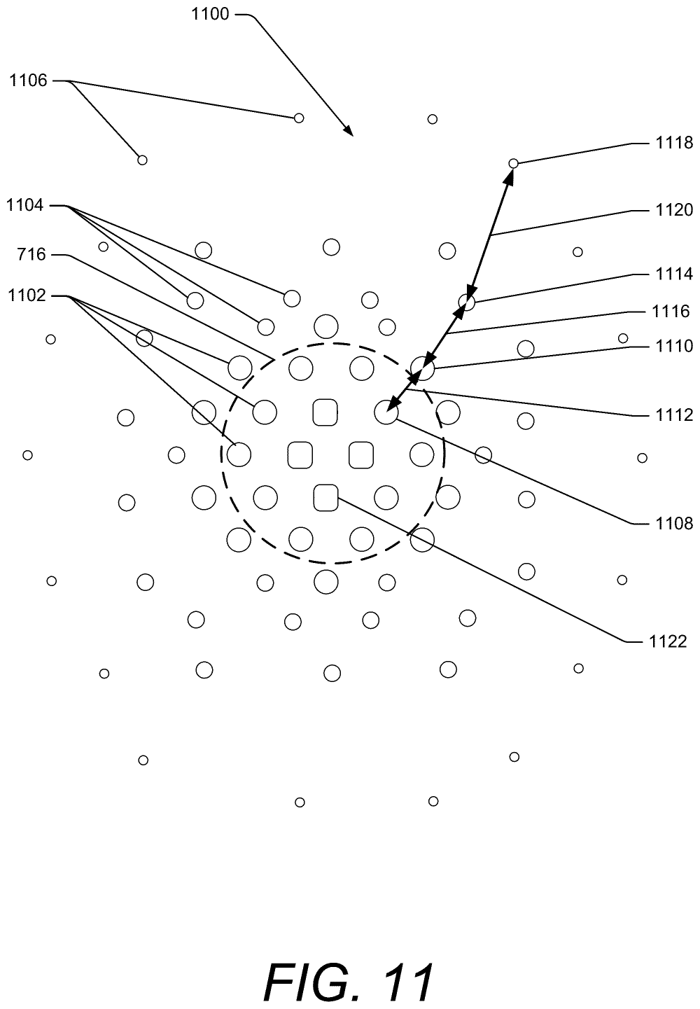

FIG. 11 illustrates a non-uniform aperture region 1100 that includes apertures of decreasing size and separated by increasing distances away from the under-display sensor 716 (represented by a dashed line in FIG. 11). The non-uniform aperture region 1100 thus combines the decreasing aperture size of the non-uniform aperture region 700 of FIG. 7 and the increasing distances between apertures of the non-uniform aperture region 900 of FIG. 9. Large apertures 1102 may be positioned over or adjacent to the under-display sensor 716. Mid-sized apertures 1104 may be positioned around outside a perimeter of the under-display sensor 716. Small apertures 1106 may be positioned beyond the mid-sized apertures 1104. Each of the apertures 1102, 1104, and 1106 may be positioned at greater distances from each other at distances away from the under-display sensor 716.

For example, a first large aperture 1108 may be positioned over the under-display sensor 716. A second large aperture 1110 may be positioned a first distance 1112 just beyond the perimeter of the under-display sensor 716. A first mid-sized aperture 1114 may be positioned at a second distance 1116 from the second large aperture 1110, with the second distance 1116 being greater than the first distance 1112. A first small aperture 1118 may be positioned at a third distance 1120 from the first mid-sized aperture 1114, with the third distance 1120 being greater than the second distance 1116. The non-uniform aperture region 1100, by seeming to diminish or fade from a position of the under-display sensor 716 through the use of apertures of decreasing sizes and that are separated by increasing distances, the appearance of the non-uniform aperture region 1100 appears to be less visually-conspicuous as compared to a region of equally-sized, equally-spaced apertures. In at least some implementations, as illustrated in FIG. 11, the apertures are non-uniform in shape. For example, from a top-down, cross-sectional perspective of a transmittance-limiting layer (e.g., transmittance-limiting layer 902), one or more apertures 1122 may form any of a variety of regular or irregular two-dimensional shapes, such as a rectangle, a circle, a pentagon, and so forth. In still further implementations, the apertures formed in a transmittance-limiting layer may define a three-dimensional volume (e.g., a through cut) forming any of a variety of regular or irregular three-dimensional shapes, such as a cylinder, a cone, a rectangular prism, and so forth.

### Example Environment

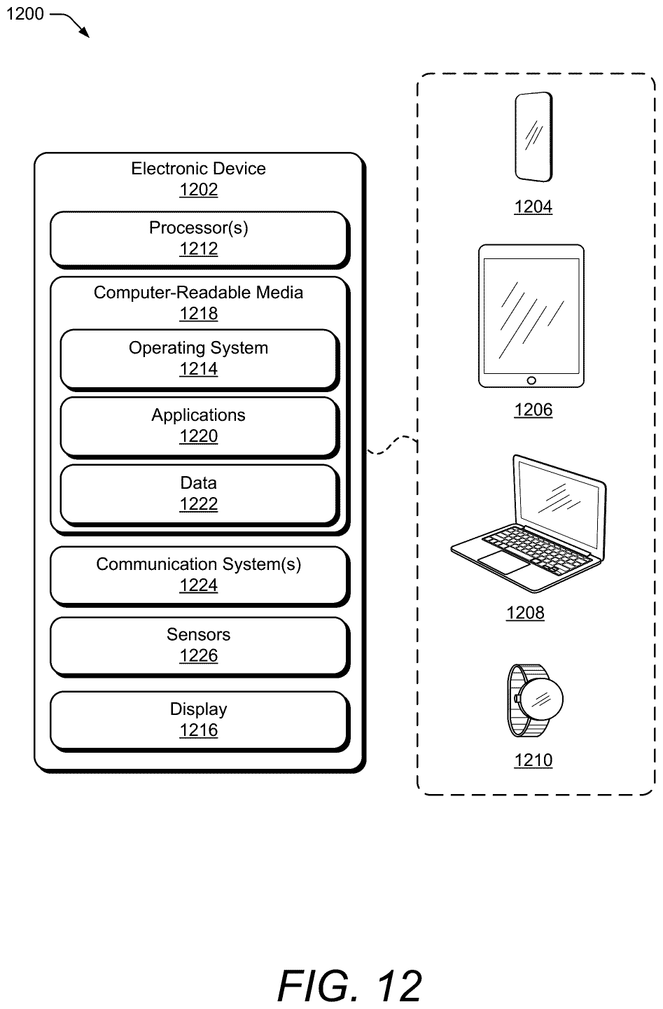

FIG. 12 illustrates an example device diagram 1200 of example electronic devices in which color-on-encapsulation patterning for inconspicuous display transmittance enhancement can be implemented. The electronic devices may include additional components and interfaces omitted from FIG. 12 for the sake of clarity.

An electronic device 1202 can be any of a variety of consumer electronic devices. As non-limiting examples, the electronic device 1202 can be a mobile phone 1204, a tablet device 1206, a laptop computer 1208, a smartwatch 1210, or another electronic device.

The electronic device 1202 includes one or more processors 1212. The processor(s) 1212 can include, as non-limiting examples, a system on a chip (SoC), an application processor (AP), a central processing unit (CPU), or a graphics processing unit (GPU). The processor(s) 1212 generally execute commands and processes utilized by the electronic device 1202 and an operating system 1214 installed thereon. For example, the processor(s) 1212 may perform operations to display graphics of the electronic device 1202 on a display 1216 and can perform other specific computational tasks.

The electronic device 1202 also includes computer-readable storage media (CRM) 1218. The CRM 1218 may be a suitable storage device configured to store device data of the electronic device 1202, user data, and multimedia data. The CRM 1218 may store the operating system 1214 that generally manages hardware and software resources (e.g., applications) of the electronic device 1202 and provides common services for applications stored on the CRM 1218 as well as the applications 1220 and data 1222. The operating system 1214 and the applications 1220 are generally executable by the processor(s) 1212 to enable communications and user interaction with the electronic device 1202. One or more processor(s) 1212, such as a GPU, perform operations to display graphics of the electronic device 1202 on the display 1216 and can perform other specific computational tasks. The processor(s) 1212 can be single-core or multiple-core processors.

The electronic device 1202 may also include communications systems 1224, such as input/output ports to support wired communications and wireless communications systems to support wireless communications such as Bluetooth, Wi-Fi, or other communications protocols. The electronic device 1202 further includes one or more sensors 1226, such as the under-display sensor previously described, the operation of which is facilitated by inclusion of a non-uniform aperture region in the display 1216, as previously described.

### Example Method of Forming a Non-Uniform Aperture Region

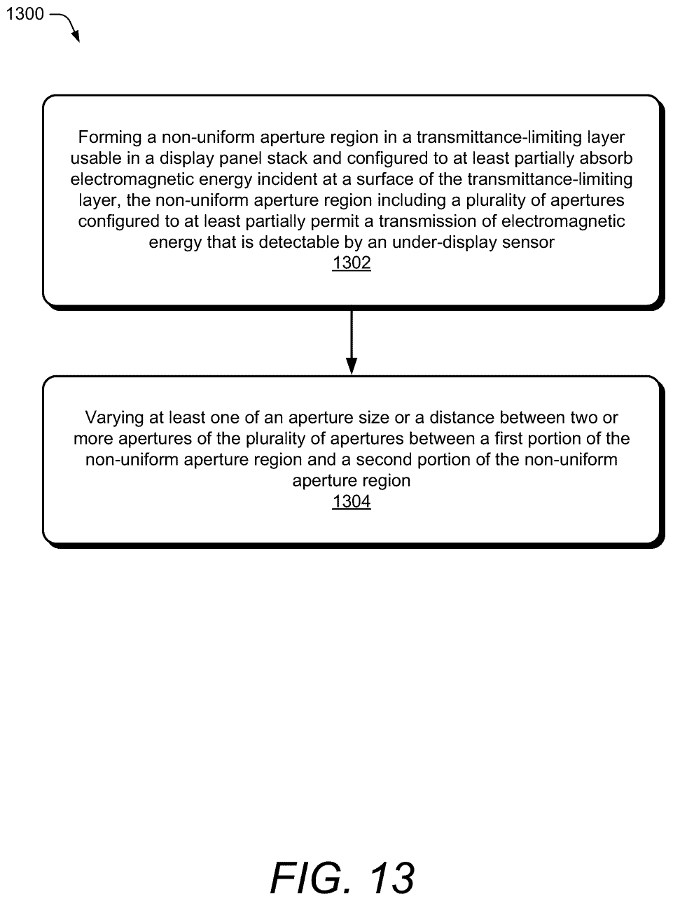

FIG. 13 illustrates a flow diagram of an example method 1300 of color-on-encapsulation patterning for color-on-encapsulation patterning for inconspicuous display transmittance enhancement. Color-on-encapsulation patterning may be implemented by forming a non-uniform aperture region in a transmittance-limiting layer like the non-uniform aperture regions described with reference to FIGS. 1-11. At a block 1302, a non-uniform aperture region is formed in a transmittance-limiting layer usable in a display panel stack and configured to at least partially absorb electromagnetic energy incident at a surface of the transmittance-limiting layer, the non-uniform aperture region including a plurality of apertures configured to at least partially permit a transmission of electromagnetic energy that is detectable by an under-display sensor. At a block 1304, at least one of an aperture size or a distance between two or more apertures of the plurality of apertures is varied between a first portion of the non-uniform aperture region and a second portion of the non-uniform aperture region.

### CONCLUSION

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying Drawings and terms discussed herein may be indicative of one or more items or terms, and thus reference may be made interchangeably to single or plural forms of the items and terms in this written description.

Terms such as “above,” “below,” or “underneath” are not intended to require any particular orientation of a device. Rather, a first layer or component, being provided “above” a second layer or component is intended to describe the first layer being at a higher Z-dimension than the second layer of component within the particular coordinate system in use. Similarly, a first layer or component, being provided “underneath” a second layer or component is intended to describe the first layer being at a lower Z-dimension than the second layer of component within the particular coordinate system in use. It will be understood that should the component be provided in another orientation, or described in a different coordinate system, then such relative terms may be changed.

Although implementations of systems and techniques for color-on-encapsulation patterning for inconspicuous display transmittance enhancement have been described in language specific to certain features and/or methods, the subject of the appended Claims is not necessarily limited to the specific features or methods described. Rather, the specific features and methods are disclosed as example implementations for color-on-encapsulation patterning for inconspicuous display transmittance enhancement.

What is claimed is:

1. A display panel stack comprising:
a cover layer;
a pixel array; and
a transmittance-limiting layer disposed between the cover layer and the pixel array configured to at least partially absorb electromagnetic energy, the transmittance-limiting layer comprising a non-uniform aperture region having a plurality of apertures arranged in a non-uniform pattern and configured to at least partially permit a transmission of the electromagnetic energy detectable by an under-display sensor.

2. The display panel stack of claim 1, wherein the plurality of apertures comprises at least one of:
perforations in the transmittance-limiting layer; or
substantially-transparent sections of the transmittance-limiting layer, the substantially-transparent sections configured to permit transmission of at least one or more wavelengths of electromagnetic energy detectable by the under-display sensor.

3. The display panel stack of claim 1, wherein at least one of an aperture size of the plurality of apertures decreases or a distance between two or more apertures of the plurality of apertures increases between the plurality of apertures between a first portion of the non-uniform aperture region and a second portion of the non-uniform aperture region.

4. The display panel stack of claim 3, wherein the first portion of the non-uniform aperture region is within a sensing field of view of the under-display sensor and the second portion of the non-uniform aperture region extends outside of the sensing field of view of the under-display sensor.

5. The display panel stack of claim 3, wherein the aperture size decreases uniformly or pseudo-randomly between the first portion of the non-uniform aperture region and the second portion of the non-uniform aperture region.

6. The display panel stack of claim 3, wherein the distance between two or more apertures of the plurality of apertures increases uniformly or pseudo-randomly between the first portion of the non-uniform aperture region and the second portion of the non-uniform aperture region.

7. The display panel stack of claim 1, wherein the transmittance-limiting layer comprises a color-on-encapsulation layer.

8. The display panel stack of claim 1, wherein the transmittance-limiting layer is configured to at least partially permit the transmission of the aspect of the electromagnetic energy that is detectable by the under-display sensor that includes a camera, a light-level sensor, or an infrared sensor.

9. The display panel stack of claim 1, wherein the transmittance-limiting layer is configured to at least partially permit a transmission of electromagnetic energy radiated by an electromagnetic emitter associated with the under-display sensor.

10. A method of forming a display panel stack, the method comprising:
forming a non-uniform aperture region in a transmittance-limiting layer usable in a display panel stack and configured to at least partially absorb electromagnetic energy incident at a surface of the transmittance-limiting layer, the non-uniform aperture region including a plurality of apertures configured to at least partially permit a transmission of electromagnetic energy; and
varying at least one of an aperture size or a distance between two or more apertures of the plurality of apertures between a first portion of the non-uniform aperture region and a second portion of the non-uniform aperture region.

11. The method of claim 10, further comprising forming the plurality of apertures by:
forming perforations in the transmittance-limiting layer; or
forming substantially-transparent sections of the transmittance-limiting layer, the substantially-transparent sections configured to permit transmission of at least one or more wavelengths of electromagnetic energy detectable by the under-display sensor.

12. The method of claim 10, further comprising at least one of decreasing an aperture size of the plurality of apertures or increasing the distance between two or more apertures of the plurality of apertures between the first portion of the non-uniform aperture region and the second portion of the non-uniform aperture region.
